(19) United States
(12) Patent Application Publication
(10) Pub. No.: US 2026/0293695 A1
(43) Pub. Date: Sep. 24, 2026

(54) CAPACITOR EMBEDDED SUBSTRATE

(71) Applicant: Murata Manufacturing Co., Ltd., Nagaokakyo-shi (JP)

(72) Inventors: Akitomo TAKAHASHI, Nagaokakyo-shi (JP); Koshi HIMEDA, Nagaokakyo-shi (JP); Shuhei YAMADA, Nagaokakyo-shi (JP)

(21) Appl. No.: 19/646,889

(22) Filed: Apr. 14, 2026

Related U.S. Application Data
(63) Continuation of application No. PCT/JP2024/033439, filed on Sep. 19, 2024.

(30) Foreign Application Priority Data
Oct. 18, 2023 (JP) 2023-179602
Jun. 5, 2024 (JP) 2024-091746

(51) Int. Cl. H10W 44/00; H10W 70/05; H10W 70/63

(52) U.S. Cl. CPC H10W 44/601; H10W 70/095; H10W 70/635

(57) ABSTRACT

A capacitor embedded substrate is provided that includes a core layer including at least one layer of a core material having a cavity, a capacitor element embedded in the cavity of the core material, and a through conductor that penetrates the core layer in a thickness direction. The through conductor includes a first through conductor that penetrates the capacitor element in the core layer to be electrically connected to a load and a power supply, and a second through conductor that penetrates the capacitor element in the core layer at a position apart from the first through conductor to be electrically connected to the load and the power supply. The first through conductor is electrically connected to a first electrode of the capacitor element. The second through conductor is electrically connected to a second electrode of the capacitor element, which has a different polarity than the first electrode.

### CROSS REFERENCE TO RELATED APPLICATIONS

This application is a continuation of International Application No. PCT/JP2024/033439, filed Sep. 19, 2024, which claims priority to Japanese Patent Application No. 2023-179602, filed Oct. 18, 2023, and to Japanese Patent Application No. 2024-091746, filed Jun. 05, 2024, the entire contents of each of which are hereby incorporated by reference in their entirety.

### TECHNICAL FIELD

The present disclosure relates to a capacitor embedded substrate.

### BACKGROUND

Japanese Patent No. 4061318 discloses a chip embedded-type printed circuit board including a central layer, an insulating layer, and a circuit layer. As disclosed therein, the central layer is provided with a through hole and a hollow portion and includes a chip inserted into the hollow portion to be fixed by plating and a circuit pattern provided on both surfaces. The insulating layer is laminated on one surface or both surfaces of the central layer and includes a through hole filled with conductive ink. The circuit layer is stacked on the insulating layer and includes a circuit pattern and a via hole formed in such a manner as to be electrically connected to the plated layer of the central layer via the through hole.

With regard to the chip embedded-type printed circuit board disclosed in Japanese Patent No. 4061318, a mode in which a chip (for example, a capacitor) is embedded in an internal layer or outside the substrate itself and the chip is integrated into a portion of the printed circuit board regardless of the size of the substrate itself is referred to as "chip embedded-type", and such a substrate is referred to as a "chip embedded-type printed circuit board".

For example, when a substrate in which a capacitor is embedded is applied to a semiconductor package substrate as the chip embedded-type printed circuit board described in Japanese Patent No. 4061318, an increase in power supply to an arithmetic device, which is an example of a load, may cause deterioration of signal quality by power supply noise. In order to suppress such deterioration of signal quality due to power supply noise, loop impedance between the load and a power supply needs to be reduced.

### SUMMARY OF THE INVENTION

In in view of the foregoing problems, it is an object of the present disclosure to provide a capacitor embedded substrate with reduced loop impedance between a load and a power supply and with suppressed deterioration of signal quality due to power supply noise.

In an exemplary aspect, a capacitor embedded substrate is provided that includes a core layer including at least one layer of a core material that includes a cavity, a capacitor element embedded in the cavity of the core material, and a through conductor that penetrates the core layer in a thickness direction. The through conductor includes a first through conductor that penetrate the capacitor element in the core layer to be electrically connected to a load and a power supply, and a second through conductor that penetrates the capacitor element in the core layer at a position apart from the first through conductor to be electrically connected to the load and the power supply. The first through conductor is electrically connected to a first electrode of the capacitor element. The second through conductor is electrically connected to a second electrode of the capacitor element, which has a polarity different from a polarity of the first electrode.

The exemplary aspects of the present disclosure invention provide a capacitor embedded substrate with reduced loop impedance between a load and a power supply and suppressed deterioration of signal quality due to power supply noise.

### BRIEF DESCRIPTION OF DRAWINGS

FIG. 1 is a schematic sectional view of an example of a capacitor embedded substrate according to a first exemplary embodiment.

FIG. 2 is an example of an equivalent circuit block diagram of the capacitor embedded substrate illustrated in FIG. 1.

FIG. 3 is a partial sectional view of the capacitor embedded substrate illustrated in FIG. 1.

FIG. 4 is an example of a plan view taken along line A-A in FIG. 3.

FIG. 5 is a schematic sectional view of another example of the capacitor embedded substrate according to the first exemplary embodiment.

FIG. 6 is an example of a plan view taken along line A-A in FIG. 5.

FIG. 7 is an example of an enlarged sectional view of part C in FIG. 3.

FIG. 8 is a schematic sectional view of an example of a capacitor embedded substrate according to a second exemplary embodiment.

FIG. 9 is an example of an equivalent circuit block diagram of the capacitor embedded substrate illustrated in FIG. 8.

FIG. 10 is another example of the equivalent circuit block diagram of the capacitor embedded substrate illustrated in FIG. 8.

FIG. 11 is a schematic sectional view of an example of a capacitor embedded substrate according to a third exemplary embodiment.

FIG. 12 is an example of an equivalent circuit block diagram of the capacitor embedded substrate illustrated in FIG. 11.

FIG. 13 is a schematic sectional view of an example of a capacitor embedded substrate according to a fourth exemplary embodiment.

FIG. 14 is an example of an equivalent circuit block diagram of the capacitor embedded substrate illustrated in FIG. 13.

FIG. 15A is a schematic diagram illustrating an example of the relationship between a frequency f and impedance |Z| when only a first capacitor element C1 is included.

FIG. 15B is a schematic diagram illustrating an example of the relationship between the frequency f and the impedance |Z| when the first capacitor element C1 and a second capacitor element C2 connected in parallel are included.

FIG. 15C is a schematic diagram illustrating another example of the relationship between the frequency f and the impedance |Z| when the first capacitor element C1 and the second capacitor element C2 connected in parallel are included.

FIG. 16 is a schematic sectional view of an example of a capacitor embedded substrate according to a fifth exemplary embodiment.

FIG. 17 is an example of an equivalent circuit block diagram of the capacitor embedded substrate illustrated in FIG. 16.

FIG. 18 is a schematic sectional view of an example of a capacitor embedded substrate according to a sixth exemplary embodiment.

FIG. 19 is a schematic sectional view of an example of a capacitor element multilayer body for manufacture of the capacitor embedded substrate illustrated in FIG. 18.

FIG. 20 is a schematic sectional view illustrating an example of a process of forming a first wiring layer on a core material.

FIG. 21 is a schematic sectional view illustrating an example of a process of forming a cavity in a core material.

FIG. 22 is a schematic sectional view illustrating an example of a process of disposing a capacitor element in a cavity of a core material.

FIG. 23 is a schematic sectional view of an example of a process of performing first resin sealing.

FIG. 24 is a schematic sectional view illustrating an example of a process of producing a core portion.

FIG. 25 is a schematic sectional view illustrating an example of a process of stacking core portions.

FIG. 26 is a schematic sectional view illustrating an example of a process of forming a core layer.

FIG. 27 is a schematic sectional view illustrating an example of a process of forming a through hole penetrating a core layer.

FIG. 28 is a schematic sectional view illustrating an example of a process of forming a through conductor.

FIG. 29 is a schematic sectional view illustrating an example of a process of performing second resin sealing.

FIG. 30 is a schematic sectional view illustrating an example of a process of forming a via conductor and wiring.

### DETAILED DESCRIPTION OF EMBODIMENTS

Hereinafter, a capacitor embedded substrate of the present disclosure will be described. It is generally noted that the exemplary aspects of the present disclosure are not limited to the following embodiments, and may be changed as appropriate without departing from the spirit of the present invention. In addition, a combination of a plurality of individual exemplary configurations described in the following embodiments is also included in the present disclosure.

In the capacitor embedded substrate of the present disclosure, a through conductor essentially includes a first through conductor and a second through conductor to be electrically connected to a load and a power supply, but the load and the power supply should be considered optional configurations/components in the capacitor embedded substrate of the present disclosure. Similarly, in an exemplary aspect in which the through conductor includes a third through conductor to be electrically connected to an interface and a load, the interface and the load are optional configurations/components in the capacitor embedded substrate of the present disclosure.

Each embodiment described below is an exemplary illustration, and needless to say, configurations described in different embodiments can be partially replaced or combined. For purposes of this disclosure, in second and subsequent embodiments, descriptions of matters common to a first embodiment will be omitted, and different points will mainly be described. In particular, similar operations and effects attributed to similar configurations will not be mentioned every time in each embodiment.

In the following description, when each embodiment is not particularly distinguished, the expression "the capacitor embedded substrate of the present disclosure" is simply used to generally refer to the embodiment(s).

For purposes of this disclosure, terms used herein for indicating relationships between elements (for example, "perpendicular", "parallel", and "orthogonal") and terms indicating shapes of elements are not expressions representing only strict meanings, but are expressions meaning to include substantially equivalent ranges, for example, including a difference of approximately several percent. Furthermore, the terms "equal" or "equivalent" as used herein are not expressions representing only cases of being perfectly equal or equivalent, but are expressions meaning to include cases of being substantially equal or equivalent, for example, including a difference of approximately several percent.

The drawings referred to below are schematic diagrams, dimensions, scales of aspect ratios, and the like may differ from those of actual products. In the drawings, the same reference characters are used for the same or corresponding parts. In addition, in the drawings, the same elements are denoted by the same reference characters to omit redundant description.

### First Exemplary Embodiment

In a capacitor embedded substrate according to the first exemplary embodiment, a core layer includes one layer of a core material.

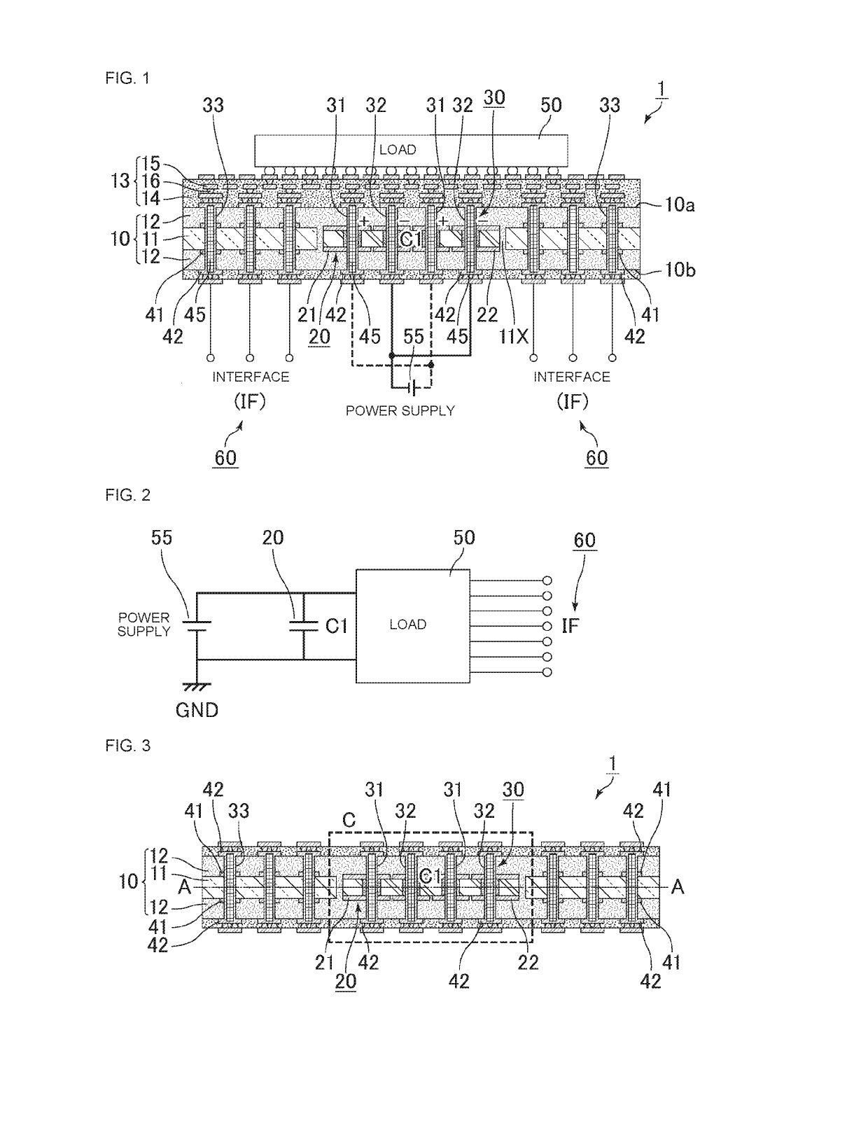

FIG. 1 is a schematic sectional view of an example of the capacitor embedded substrate according to the first exemplary embodiment. FIG. 2 is an example of an equivalent circuit block diagram of the capacitor embedded substrate illustrated in FIG. 1. In the equivalent circuit block diagram of FIG. 2, GND indicates a ground (e.g., a ground connection). The same applies to equivalent circuit block diagrams other than FIG. 2.

As generally shown, a capacitor embedded substrate 1 illustrated in FIG. 1 includes a core layer 10, a capacitor element 20, and a through conductor 30.

The core layer 10 includes a first main surface 10a and a second main surface 10b facing one another in a thickness direction (upward-downward or vertical direction in FIG. 1).

The core layer 10 includes a core material 11 including a cavity 11X. The capacitor element 20 is embedded in the cavity 11X of the core material 11. In the example illustrated in FIG. 1, the core layer 10 includes one layer of the core material 11 in the thickness direction. The core material 11 includes an insulating material.

In an exemplary aspect, the core layer 10 further includes an adhesive layer 12 provided in such a manner as to cover the core material 11 and the capacitor element 20. The adhesive layer 12 may be provided on both main surfaces of the core material 11 or may be provided on either one of the main surfaces. The adhesive layer 12 includes an insulating material.

As illustrated in FIG. 1, a portion of the cavity 11X where the capacitor element 20 is not embedded (that is, a portion between the core material 11 and the capacitor element 20) is filled with an insulating material such as the adhesive layer 12 in an exemplary aspect.

As illustrated in FIG. 1, a first wiring layer 41 can be provided on at least one main surface of the core material 11. Moreover, when the core layer 10 includes the adhesive layer 12, a second wiring layer 42 is provided on at least one main surface of the adhesive layer 12.

Moreover, a redistribution layer 13 may be provided on at least one main surface of the core layer 10. The redistribution layer 13 may be provided on both main surfaces of the core layer 10 or may be provided on either one of the main surfaces.

The redistribution layer 13 can be a multilayer wiring layer in an exemplary aspect. The redistribution layer 13 includes, for example, an insulating layer 14 and wiring 15. The insulating layer 14 includes a via conductor 16 therein. The via conductor 16 electrically connects the wiring 15 in different layers in the redistribution layer 13.

The through conductor 30 is provided in such a manner as to penetrate the core layer 10 in the thickness direction.

The through conductor 30 only needs to be provided on at least an inner wall surface of a through hole penetrating the core layer 10 in the thickness direction. That is, the through conductor 30 may be provided only on the inner wall surface of the through hole or may be provided throughout the entire inside of the through hole.

As illustrated in FIG. 1, a resin filling part 45 filled with a resin material may be provided inside the through conductor 30. In this case, the resin filling part 45 is provided in a space surrounded by the through conductor 30 in the through hole penetrating the core layer 10 in the thickness direction. When the space in the through hole is eliminated by the resin filling part 45 being provided, occurrence of delamination of the through conductor 30 is suppressed. It is noted that the resin filling part 45 may be a conductor or an insulator in exemplary aspects.

When seen in the thickness direction, the through conductor 30 can be provided over the entire periphery of the through hole penetrating the core layer 10 in the thickness direction according to an exemplary aspect.

The through conductor 30 includes a first through conductor 31 and a second through conductor 32.

The first through conductor 31 is a through conductor provided in such a manner as to penetrate the capacitor element 20 in the core layer 10 to be electrically connected to a load 50 and a power supply 55.

The first through conductor 31 is electrically connected to a first electrode 21 (for example, an anode) of the capacitor element 20.

The second through conductor 32 is a through conductor provided in such a manner as to penetrate the capacitor element 20 in the core layer 10 at a position apart from the first through conductor 31 to be electrically connected to the load 50 and the power supply 55.

The second through conductor 32 is electrically connected to a second electrode 22 (for example, a cathode) of the capacitor element 20 having a polarity different from a polarity of the first electrode 21.

In the capacitor embedded substrate 1 illustrated in FIG. 1, the first through conductor 31 and the second through conductor 32 can shorten a wiring path between the load 50 and the power supply 55. Therefore, loop impedance between the load 50 and the power supply 55 can be reduced. As a result, deterioration of signal quality due to power supply noise is prevented or suppressed.

In an exemplary aspect, except for a portion of the capacitor element 20 connected to the first electrode 21, as illustrated in FIG. 1, a space between the first through conductor 31 and the capacitor element 20 is filled with an insulating material.

It should be appreciated that the number of first through conductors 31 is not particularly limited and may be one or two or more.

It should be appreciated that a cross-sectional shape of the first through conductor 31 perpendicular to the thickness direction is not particularly limited, and is, for example, a circular shape in an exemplary aspect.

A diameter of the first through conductor 31 may be constant or may be different in the thickness direction. Note that the diameter of the through conductor indicates a diameter in a case in which a planar shape is a circular shape, and indicates an equivalent circle diameter in a case in which the planar shape is a shape other than a circular shape.

In an exemplary aspect, except for a portion of the capacitor element 20 connected to the second electrode 22, as illustrated in FIG. 1, a space between the second through conductor 32 and the capacitor element 20 is filled with an insulating material in an exemplary aspect.

It should be appreciated that the number of second through conductors 32 is not particularly limited and may be one or two or more. The number of second through conductors 32 may be the same as the number of first through conductors 31, may be larger than the number of first through conductors 31, or may be smaller than the number of first through conductors 31.

It should be appreciated that a cross-sectional shape of the second through conductor 32 perpendicular to the thickness direction is not particularly limited, and is, for example, a circular shape. The cross-sectional shape of the second through conductor 32 may be the same as or different from the cross-sectional shape of the first through conductor 31.

A diameter of the second through conductor 32 may be constant or may be different in the thickness direction. The diameter of the second through conductor 32 may be the same as or different from the diameter of the first through conductor 31.

Examples of the load 50 include an arithmetic device including a semiconductor integrated circuit.

The power supply 55 is configured to supply direct current voltage to, for example, a voltage regulator (not illustrated). The voltage regulator includes an active element, such as a semiconductor switching element, and controls the duty of the active element to adjust the direct current voltage supplied from the power supply 55 to a voltage level suitable for the load 50.

As illustrated in FIG. 1, the first through conductor 31 and the second through conductor 32 can be electrically connected to the load 50 at an end portion closer to the first main surface 10a (e.g., the upper surface in FIG. 1) and electrically connected to the power supply 55 at an end portion closer to the second main surface 10b (the lower surface in FIG. 1).

Moreover, as illustrated in FIG. 1, the first through conductor 31 and the second through conductor 32 are electrically connected to the load 50 directly below the load 50 in a plan view.

In an exemplary aspect, the through conductor 30 includes a third through conductor 33.

The third through conductor 33 is a through conductor provided in such a manner as to penetrate the core material 11 without penetrating the capacitor element 20 in the core layer 10 to be electrically connected to an interface 60 and the load 50.

It should be appreciated that the number of third through conductors 33 is not particularly limited and may be one or two or more. The number of third through conductors 33 may be the same as the number of first through conductors 31, may be larger than the number of first through conductors 31, or may be smaller than the number of first through conductors 31. Moreover, the number of third through conductors 33 may be the same as the number of second through conductors 32, may be larger than the number of second through conductors 32, or may be smaller than the number of second through conductors 32.

It should be appreciated that a cross-sectional shape of the third through conductor 33 perpendicular to the thickness direction is not particularly limited, and is, for example, a circular shape. The cross-sectional shape of the third through conductor 33 may be the same as or different from the cross-sectional shape of the first through conductor 31. The cross-sectional shape of the third through conductor 33 may be the same as or different from the cross-sectional shape of the second through conductor 32.

A diameter of the third through conductor 33 may be constant or may be different in the thickness direction. The diameter of the third through conductor 33 may be the same as or different from the diameter of the first through conductor 31. The diameter of the third through conductor 33 may be the same as or different from the diameter of the second through conductor 32.

As illustrated in FIG. 1, the third through conductor 33 can be electrically connected to the load 50 at an end portion closer to the first main surface 10a (e.g., the upper surface in FIG. 1) and electrically connected to the interface 60 at an end portion closer to the second main surface 10b (e.g., the lower surface in FIG. 1).

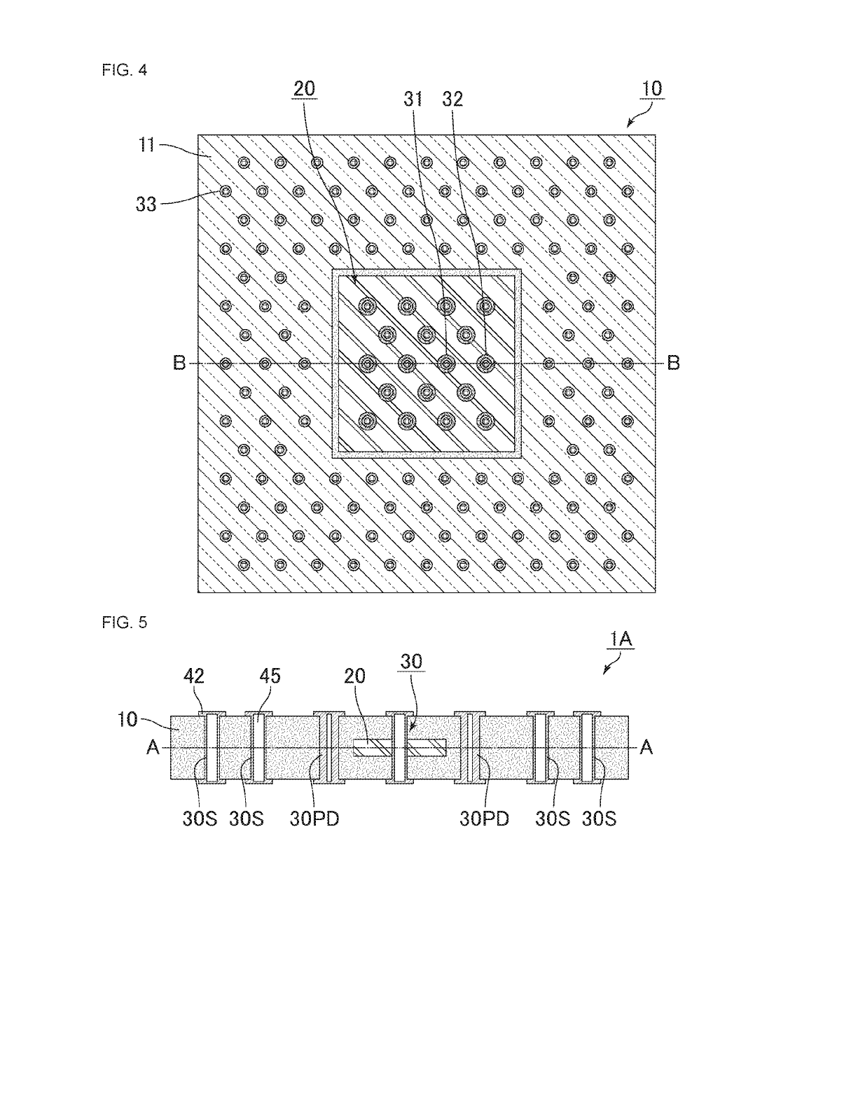

FIG. 3 is a partial sectional view of the capacitor embedded substrate illustrated in FIG. 1. In FIG. 3, the redistribution layer 13, the load 50, the power supply 55, and the interface 60 are omitted from FIG. 1. FIG. 4 is an example of a plan view taken along line A-A in FIG. 3. Note that FIG. 3 is also a sectional view taken along line B-B in FIG. 4.

As illustrated in FIG. 4, in a plan view in the thickness direction, the third through conductor 33 is disposed on an outer peripheral side of the first through conductor 31 and the second through conductor 32.

It is noted that the first through conductor 31 and the second through conductor 32 may have shapes, densities, arrangements, and the like that are the same as or different from those of the third through conductor 33 in various exemplary aspects.

In an exemplary aspect, the first through conductor 31 and the second through conductor 32 are disposed at equal intervals as a whole. In other words, center-to-center distances between the through conductors can be equivalent in an exemplary aspect. In a case in which the first through conductors 31 and the second through conductors 32 are disposed at equal intervals as a whole, the first through conductors 31 may be disposed at equal intervals or do not necessarily have to be disposed at equal intervals. Similarly, the second through conductors 32 may be disposed at equal intervals or do not necessarily have to be disposed at equal intervals.

Herein, a center of the through conductor refers to a center of a minimum circle enclosing the through conductor in a plan view in the thickness direction. Therefore, the center-to-center distance between the through conductors indicates a length of a line segment connecting the centers of the through conductors obtained by the above method. The same applies to a center-to-center distance between the first through conductors, a center-to-center distance between the second through conductors, and a center-to-center distance between the first through conductor and the second through conductor.

For example, as illustrated in FIG. 4, the first through conductors 31 and the second through conductors 32 may be disposed in a hexagonal arrangement as a whole. In the hexagonal arrangement, the first through conductor 31 or the second through conductor 32 is disposed at each vertex of a regular hexagonal shape and at a center of the regular hexagonal shape.

Alternatively, the first through conductors 31 and the second through conductors 32 may be disposed in a square arrangement as a whole. In the square arrangement, the first through conductor 31 or the second through conductor 32 is disposed at each vertex of a square shape.

Similarly, the third through conductors 33 can be disposed at equal intervals as a whole.

For example, as illustrated in FIG. 4, the third through conductors 33 may be disposed in a hexagonal arrangement as a whole. In the hexagonal arrangement, the third through conductor 33 is disposed at each vertex of a regular hexagonal shape and at a center of the regular hexagonal shape.

Alternatively, the third through conductors 33 may be disposed in a square arrangement as a whole. In the square arrangement, the third through conductor 33 is disposed at each vertex of a square shape.

For example, the first through conductor 31 and the second through conductor 32 can be used as through conductors for power supply (Power/GND), and the third through conductor 33 can be used as a through conductor for signal transmission (Signal).

It is generally noted that a power supply (Power/GND) line requires a higher current capacity than a signal transmission (Signal) line, thereby requiring a wide conductor area. Therefore, in a plan view illustrated in FIG. 4, when a conductor area of the through conductor for power supply (Power) is Vp and a conductor area of the through conductor for power supply (GND) is Vd among the through conductors for power supply (Power/GND), and a conductor area of the through conductor for signal transmission (Signal) is Vs, preferably, Vp is larger than Vs and Vd is larger than Vs. That is, the relationships Vs < Vp and Vs < Vd are satisfied in an exemplary aspect. In this case, more preferably, Vp and Vd are equivalent.

The conductor area of the through conductor can be adjusted by, for example, changing (1) the diameter of the through conductor, (2) a conductor thickness of the through conductor, or (3) both the diameter and the conductor thickness of the through conductor.

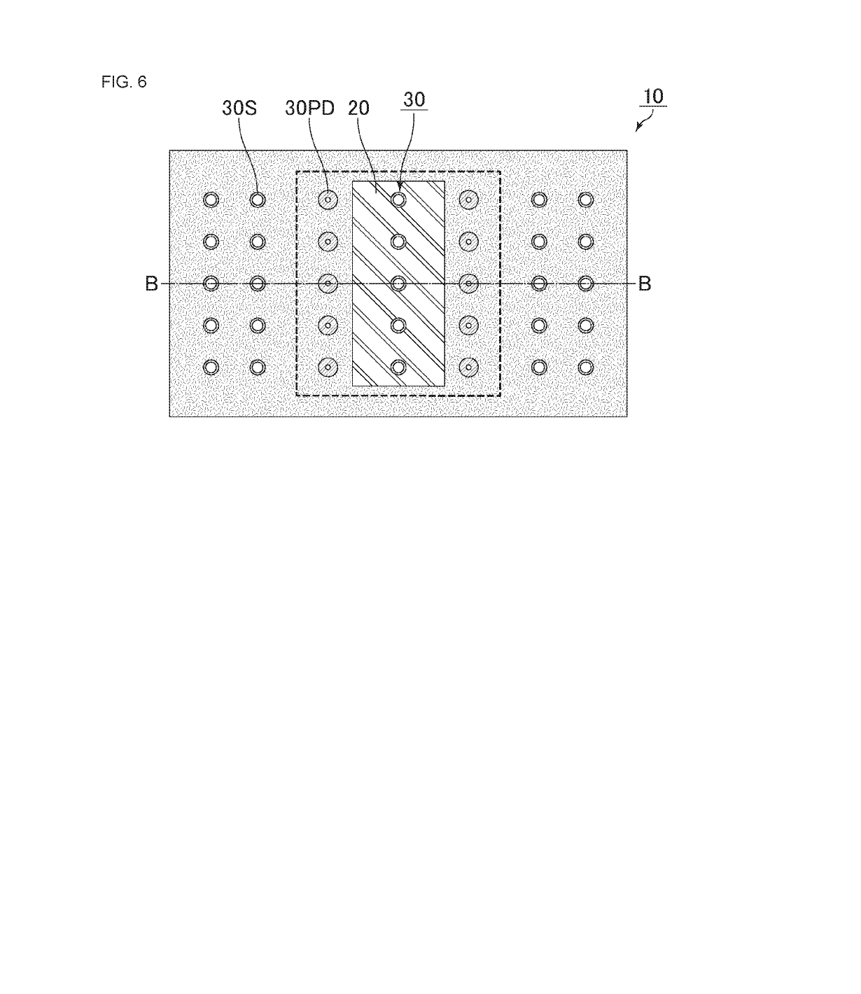

FIG. 5 is a schematic sectional view of another example of the capacitor embedded substrate according to the first exemplary embodiment. FIG. 5 is more simplified than FIG. 3. FIG. 6 is an example of a plan view taken along line A-A in FIG. 5. Note that FIG. 5 is also a sectional view taken along line B-B in FIG. 6.

In a capacitor embedded substrate 1A illustrated in FIG. 5, as illustrated in FIGS. 5 and 6, a through conductor 30PD for power supply (Power/GND) is disposed not inside the capacitor element 20 but outside the capacitor element 20. In an exemplary aspect, a through conductor 30S for signal transmission (Signal) is disposed on an outer peripheral side of the through conductor 30PD for power supply (Power/GND).

In a plan view illustrated in FIG. 6, in a case in which a conductor area of the through conductor 30PD for power supply (Power) is Vp and a conductor area of the through conductor 30PD for power supply (GND) is Vd among the through conductors 30PD for power supply (Power/GND), and a conductor area of the through conductor 30S for signal transmission (Signal) is Vs, Vp is larger than Vs and Vd is larger than Vs. That is, the relationships Vs < Vp and Vs < Vd are satisfied. In this case, more preferably, Vp and Vd are equivalent in an exemplary aspect. In this manner, when the through conductor 30PD for power supply (Power/GND) is disposed outside the capacitor element 20, the conductor area of the through conductor of this portion may be large.

In the example illustrated in FIGS. 5 and 6, both the diameter and the conductor thickness of the through conductor are increased to increase the conductor area.

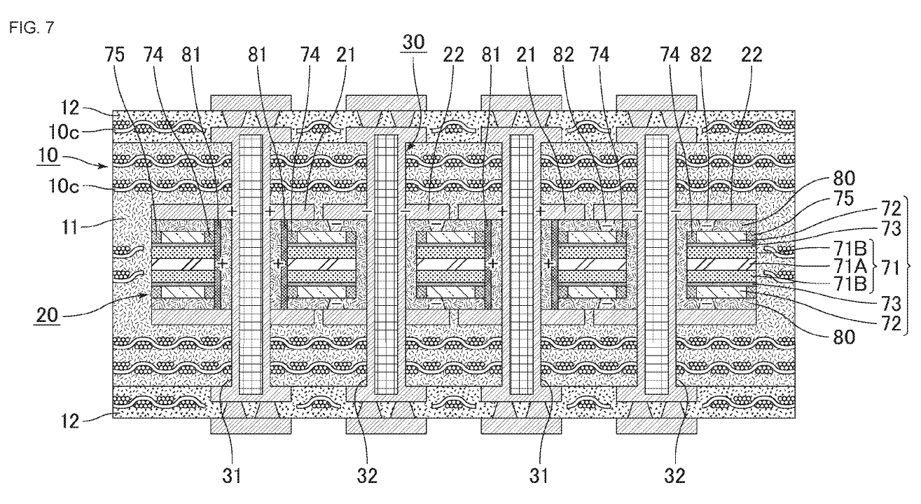

FIG. 7 is an example of an enlarged sectional view of part C in FIG. 3.

As illustrated in FIG. 7, the capacitor element 20 includes, for example, a capacitor part 70 and a sealing layer 80 provided in such a manner as to cover at least one main surface of the capacitor part 70.

The capacitor part 70 includes an anode plate 71 including a porous portion 71B on at least one main surface of a core portion 71A, a dielectric layer 73 provided on a surface of the porous portion 71B, and a cathode layer 72 provided on a surface of the dielectric layer 73. Accordingly, the capacitor part 70 constitutes an electrolytic capacitor. In the example illustrated in FIG. 7, the anode plate 71 includes the porous portion 71B on both main surfaces of the core portion 71A, but may include the porous portion 71B on only either one of the main surfaces of the core portion 71A.

The cathode layer 72 includes, for example, a solid electrolyte layer provided on a surface of the dielectric layer 73. In an exemplary aspect, the cathode layer 72 further includes a conductor layer provided on a surface of the solid electrolyte layer. When the cathode layer 72 includes a solid electrolyte layer, the capacitor part 70 constitutes a solid electrolytic capacitor.

According to an exemplary aspect, an insulating mask layer 74 may be provided around the first through conductor 31 or the second through conductor 32 on at least one main surface of the anode plate 71.

Moreover, on at least one main surface of the anode plate 71, an insulating mask layer 75 may be provided in such a manner as to surround a periphery of the cathode layer 72. By the insulating mask layer 75 surrounding the periphery of the cathode layer 72, insulation between the anode plate 71 and the cathode layer 72 is ensured, which prevents a short circuit between the anode plate 71 and the cathode layer 72.

The sealing layer 80 may be provided in such a manner as to cover either one of the main surfaces (e.g., the upper surface or the lower surface in FIG. 7) of the capacitor part 70, but as illustrated in FIG. 7, the sealing layer 80 is provided in such a manner as to cover both main surfaces (the upper and lower surfaces in FIG. 7) of the capacitor part 70. The sealing layer 80 protects the capacitor part 70.

In various exemplary aspects, the sealing layer 80 may include only one layer or include two or more layers. When the sealing layer 80 includes two or more layers, materials included in the respective layers may be the same or different.

The sealing layer 80 is formed in such a manner as to seal the capacitor part 70 by, for example, a method of thermocompression-bonding of an insulating resin sheet, a method of application and then thermosetting of an insulating resin paste, or the like.

When the first electrode 21 of the capacitor element 20 is electrically connected to the anode plate 71, the anode plate 71 is electrically connected to the first electrode 21 via, for example, an anode through conductor 81 penetrating the capacitor element 20. On the other hand, when the second electrode 22 of the capacitor element 20 is electrically connected to the cathode layer 72, the cathode layer 72 is electrically connected to the second electrode 22 via, for example, a cathode via conductor 82 penetrating the sealing layer 80.

As illustrated in FIG. 7, the core material 11 included in the core layer 10 includes an insulating material containing a glass cloth 10c. The core material 11 containing the glass cloth 10c can increase rigidity of the entire substrate. The glass cloth 10c includes glass yarns woven, for example, in a lattice pattern.

The core material 11 containing the glass cloth 10c is formed by using, for example, a prepreg in which a glass cloth is impregnated in advance with an insulating resin.

Similarly, when the core layer 10 includes the adhesive layer 12, the adhesive layer 12 includes an insulating material containing the glass cloth 10c. The adhesive layer 12 containing the glass cloth 10c can increase rigidity of the entire substrate.

The adhesive layer 12 containing the glass cloth 10c is formed by using, for example, a prepreg in which a glass cloth is impregnated in advance with an insulating resin.

It is noted that when both the core material 11 and the adhesive layer 12 include an insulating material containing the glass cloth 10c, a boundary between the core material 11 and the adhesive layer 12 does not necessarily appear clearly.

It is also noted that, in the capacitor embedded substrate 1, electronic devices, such as a decoupling capacitor for noise countermeasure, a choke inductor, a diode element for surge protection, and a resistance element for voltage division may be mounted.

Further, the technology using the through conductor in the capacitor embedded substrate of the present disclosure can be applied not only to the electrolytic capacitor described above but also to another capacitor. For example, in a multilayer ceramic capacitor including a first electrode and a second electrode, the effect of the present disclosure can be provided even in a configuration in which the first electrode and the second electrode are embedded inside the substrate in such a manner as to face one another in the thickness direction. The same applies to the following embodiments, and a type of capacitor is not limited to an electrolytic capacitor.

### Second Exemplary Embodiment

In a capacitor embedded substrate according to a second exemplary embodiment, a core material of the same layer includes a plurality of cavities, and a capacitor element is embedded in each of the cavities.

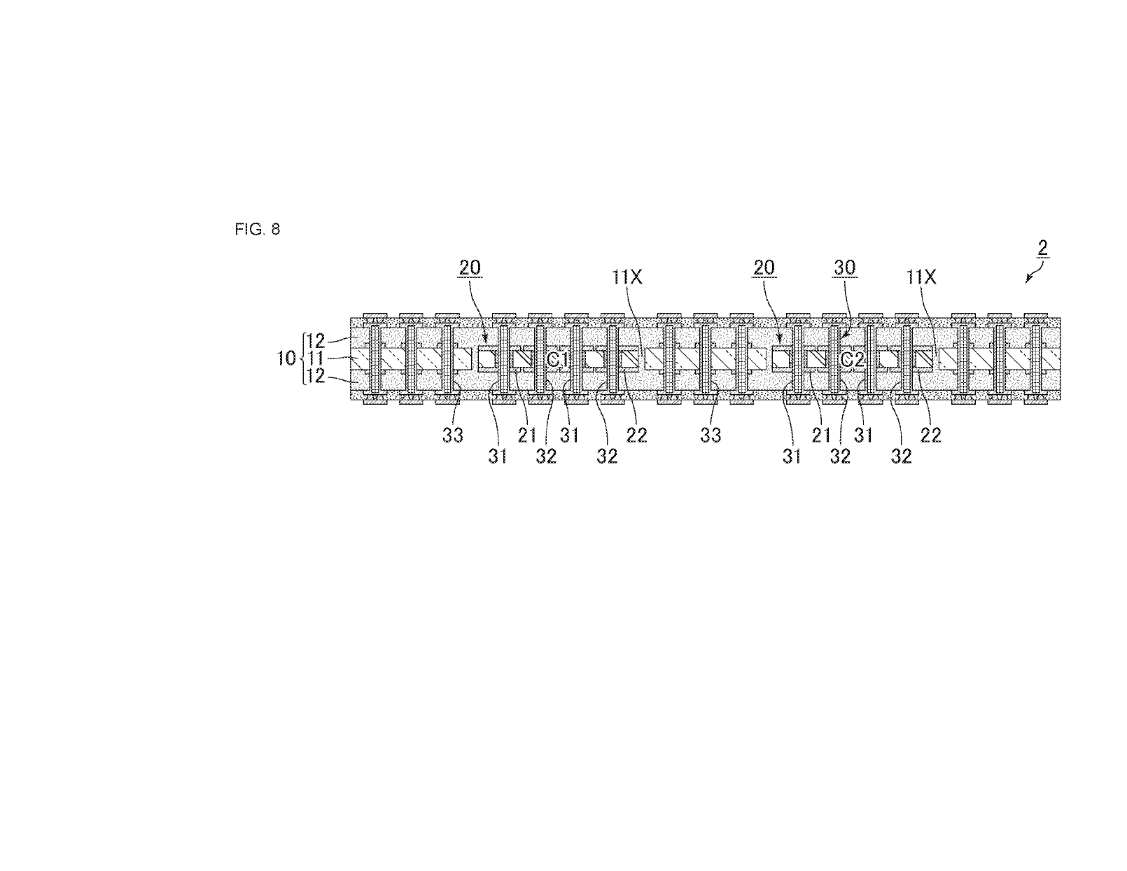

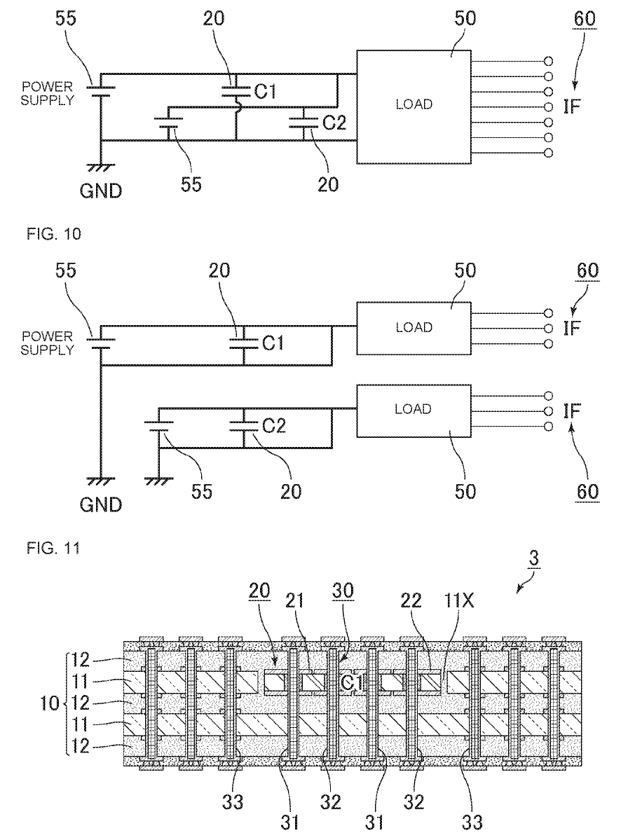

FIG. 8 is a schematic sectional view of an example of the capacitor embedded substrate according to the second exemplary embodiment. Similarly to FIG. 3, in FIG. 8, the redistribution layer 13, the load 50, the power supply 55, and the interface 60 are omitted. FIG. 9 is an example of an equivalent circuit block diagram of the capacitor embedded substrate illustrated in FIG. 8. FIG. 10 is another example of the equivalent circuit block diagram of the capacitor embedded substrate illustrated in FIG. 8.

In a capacitor embedded substrate 2 illustrated in FIG. 8, the core material 11 of the same layer includes a plurality of cavities 11X, and one or more of the capacitor elements 20 can be embedded in each of the cavities 11X.

The capacitor embedded substrate 2 illustrated in FIG. 8 can support a multi-phase power supply as illustrated in FIG. 9. Moreover, as illustrated in FIG. 10, power supply to a plurality of loads 50 (e.g., chiplets and the like) mounted on the same substrate can be supported by a single substrate.

It should be appreciated that the number of cavities 11X included in the core material 11 of the same layer is not particularly limited as long as it is two or more. All the cavities 11X may have the same size, shape, and the like, or one or some or all of them may have different sizes, shapes, and the like.

It is noted that the configurations of the capacitor elements 20 embedded in the respective cavities 11X may be all the same, or one or some or all of them may be different.

### Third Exemplary Embodiment

In a capacitor embedded substrate according to a third exemplary embodiment, a core layer includes a plurality of layers of a core material in the thickness direction, and at least one layer of the core material includes a cavity.

FIG. 11 is a schematic sectional view of an example of the capacitor embedded substrate according to the third exemplary embodiment. Similarly to FIG. 3, in FIG. 11, the redistribution layer 13, the load 50, the power supply 55, and the interface 60 are omitted. FIG. 12 is an example of an equivalent circuit block diagram of the capacitor embedded substrate illustrated in FIG. 11. The equivalent circuit block diagram illustrated in FIG. 12 is the same as the equivalent circuit block diagram illustrated in FIG. 2.

In a capacitor embedded substrate 3 illustrated in FIG. 11, the core layer 10 includes a plurality of layers of the core material 11 in the thickness direction, and at least one layer of the core material 11 includes the cavity 11X.

In the capacitor embedded substrate 3 illustrated in FIG. 11, the entire substrate can have increased rigidity as compared to the case in which the core layer 10 includes one layer of the core material. In addition, warpage of the substrate can be suppressed.

Furthermore, in the capacitor embedded substrate 3 illustrated in FIG. 11, defects, such as disconnection/short-circuit failure due to a pattern defect of wiring in the redistribution layer 13, and solder cracks, are suppressed.

It should be appreciated that the number of layers of the core material 11 included in the core layer 10 is not particularly limited as long as it is two or more. Moreover, the number of layers of the core material 11 including the cavity 11X may be one or two or more. In an exemplary aspect, the adhesive layer 12 is provided between the core materials 11.

In the case in which, among a plurality of layers of the core material 11, two or more layers of the core material 11 include the cavities 11X, the capacitor element 20 is embedded in each of the cavities 11X.

As in the second embodiment, the core material 11 of the same layer may include a plurality of cavities 11X. When two or more layers of the core material 11 include the cavities 11X, all the core material 11 of the layers may include the same number of cavities 11X, or one or some or all of them may include different numbers of cavities 11X.

It is noted that the configurations of the capacitor elements 20 embedded in the respective cavities 11X may be all the same, or one or some or all of them may be different.

### Fourth Exemplary Embodiment

In a capacitor embedded substrate according to a fourth exemplary embodiment, a first capacitor element and a second capacitor element embedded in respective cavities of a core material of different layers are connected in parallel.

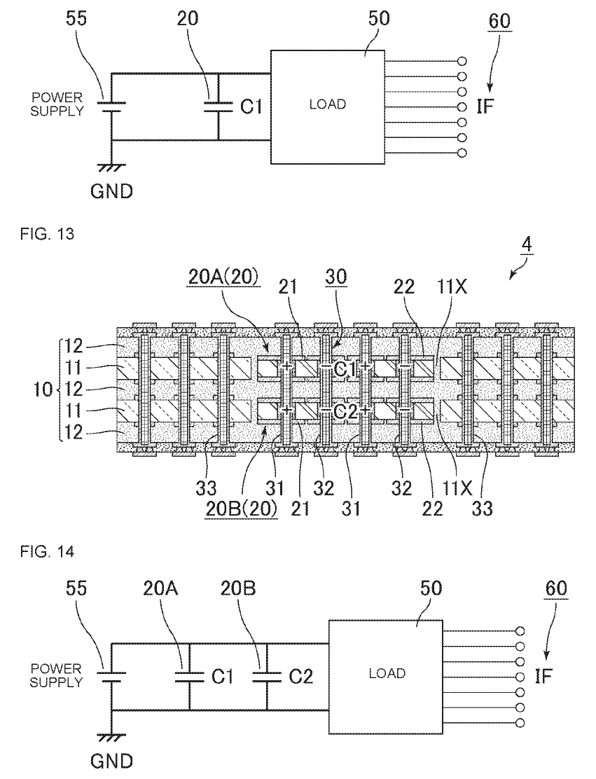

FIG. 13 is a schematic sectional view of an example of the capacitor embedded substrate according to the fourth exemplary embodiment. Similarly to FIG. 3, in FIG. 13, the redistribution layer 13, the load 50, the power supply 55, and the interface 60 are omitted. FIG. 14 is an example of an equivalent circuit block diagram of the capacitor embedded substrate illustrated in FIG. 13.

In a capacitor embedded substrate 4 illustrated in FIG. 13, the capacitor element 20 includes a first capacitor element 20A and a second capacitor element 20B embedded in the respective cavities 11X of the core material 11 of different layers.

The first through conductor 31 is provided in such a manner as to penetrate the first capacitor element 20A and is electrically connected to the first electrode 21 of the first capacitor element 20A, and is also provided in such a manner as to penetrate the second capacitor element 20B and is electrically connected to the first electrode 21 of the second capacitor element 20B having the same polarity as that of the first electrode 21 of the first capacitor element 20A.

The second through conductor 32 is provided in such a manner as to penetrate the first capacitor element 20A and is electrically connected to the second electrode 22 of the first capacitor element 20A, and is also provided in such a manner as to penetrate the second capacitor element 20B and is electrically connected to the second electrode 22 of the second capacitor element 20B having the same polarity as that of the second electrode 22 of the first capacitor element 20A.

Accordingly, the first capacitor element 20A and the second capacitor element 20B are connected in parallel. Configurations of the first capacitor element 20A and the second capacitor element 20B may be the same or different.

FIG. 15A is a schematic diagram illustrating an example of the relationship between a frequency f and impedance |Z| when only a first capacitor element C1 is included. FIG. 15B is a schematic diagram illustrating an example of the relationship between the frequency f and the impedance |Z| when the first capacitor element C1 and a second capacitor element C2 connected in parallel are included. FIG. 15C is a schematic diagram illustrating another example of the relationship between the frequency f and the impedance |Z| when the first capacitor element C1 and the second capacitor element C2 connected in parallel are included.

In the capacitor embedded substrate 4 illustrated in FIG. 13, as illustrated in FIG. 15B, when resonant frequencies fr of the first capacitor element 20A and the second capacitor element 20B are the same or close to one another, that is, when fr_{C1} ≈ fr_{C2}, the impedance |Z| in that frequency range can be attenuated more than that of the case in FIG. 15A.

Alternatively, as illustrated in FIG. 15C, when the resonant frequencies fr of the first capacitor element 20A and the second capacitor element 20B are different (do not overlap), that is, when fr_{C1}≠ fr_{C2}, the impedance |Z| in a wider frequency range can be attenuated more than that of the case in FIG. 15A.

Although not illustrated in FIG. 13, the capacitor element 20 with a higher resonant frequency fr between the first capacitor element 20A and the second capacitor element 20B is disposed closer to the load 50 in an exemplary aspect. In this case, inductance L can be reduced.

The capacitor embedded substrate 4 illustrated in FIG. 13 may include the capacitor element 20 other than the first capacitor element 20A and the second capacitor element 20B.

### Fifth Exemplary Embodiment

In a capacitor embedded substrate according to a fifth exemplary embodiment, a first capacitor element and a second capacitor element embedded in respective cavities of a core material of different layers are connected in series.

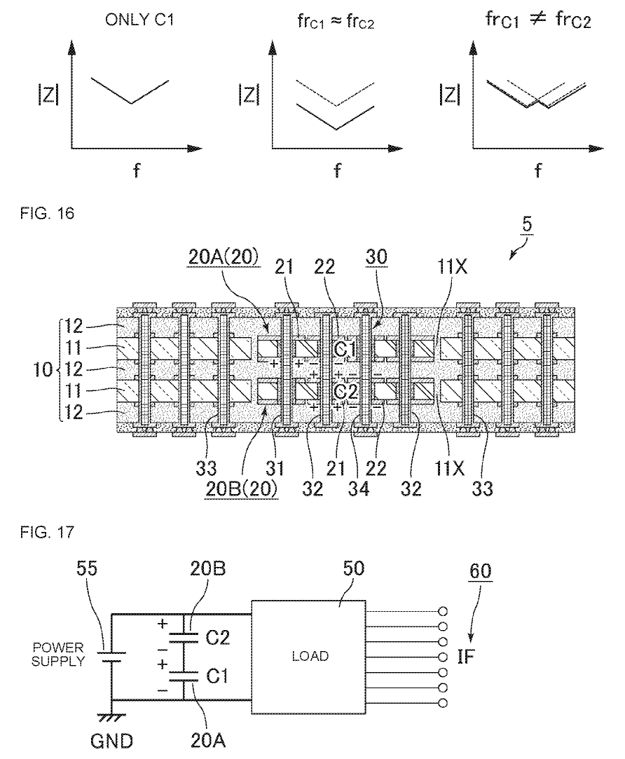

FIG. 16 is a schematic sectional view of an example of the capacitor embedded substrate according to the fifth exemplary embodiment. Similarly to FIG. 3, in FIG. 16, the redistribution layer 13, the load 50, the power supply 55, and the interface 60 are omitted. FIG. 17 is an example of an equivalent circuit block diagram of the capacitor embedded substrate illustrated in FIG. 16.

In the capacitor embedded substrate 5 illustrated in FIG. 16, the capacitor element 20 includes the first capacitor element 20A and the second capacitor element 20B embedded in the respective cavities 11X of the core material 11 of different layers.

The through conductor 30 further includes a fourth through conductor 34 provided in such a manner as to penetrate the capacitor element 20 in the core layer 10 at a position apart from the first through conductor 31 and the second through conductor 32.

The first through conductor 31 is provided in such a manner as to penetrate the first capacitor element 20A and is electrically connected to the first electrode 21 of the first capacitor element 20A, and is also provided in such a manner as to penetrate the second capacitor element 20B and is not electrically connected to either the first electrode 21 of the second capacitor element 20B or the second electrode 22 of the second capacitor element 20B. The first electrode 21 of the second capacitor element 20B has the same polarity as that of the first electrode 21 of the first capacitor element 20A. The second electrode 22 of the second capacitor element 20B has the same polarity as that of the second electrode 22 of the first capacitor element 20A.

The second through conductor 32 is provided in such a manner as to penetrate the first capacitor element 20A and is electrically connected to the second electrode 22 of the first capacitor element 20A, and is also provided in such a manner as to penetrate the second capacitor element 20B and is electrically connected to the first electrode 21 of the second capacitor element 20B.

The fourth through conductor 34 is provided in such a manner as to penetrate the first capacitor element 20A and is not electrically connected to either the first electrode 21 of the first capacitor element 20A or the second electrode 22 of the first capacitor element 20A, and is also provided in such a manner as to penetrate the second capacitor element 20B and is electrically connected to the second electrode 22 of the second capacitor element 20B.

Accordingly, the first capacitor element 20A and the second capacitor element 20B are connected in series. Configurations of the first capacitor element 20A and the second capacitor element 20B may be the same or different.

In the capacitor embedded substrate 5 illustrated in FIG. 16, the first capacitor element 20A and the second capacitor element 20B are connected in series, and thereby the capacitor element 20 can have an increased withstand voltage.

The capacitor embedded substrate 5 illustrated in FIG. 16 may include the capacitor element 20 other than the first capacitor element 20A and the second capacitor element 20B.

### Sixth Exemplary Embodiment

In a capacitor embedded substrate according to a sixth exemplary embodiment, a plurality of capacitor elements is embedded in a cavity of a core material of the same layer in the thickness direction.

FIG. 18 is a schematic sectional view of an example of the capacitor embedded substrate according to the sixth exemplary embodiment. Similarly to FIG. 3, in FIG. 18, the redistribution layer 13, the load 50, the power supply 55, and the interface 60 are omitted.

In a capacitor embedded substrate 6 illustrated in FIG. 18, a plurality of capacitor elements 20 is embedded in the cavity 11X of the core material 11 of the same layer in the thickness direction.

It is noted that the number of capacitor elements 20 embedded in the cavity 11X of the core material 11 of the same layer is not particularly limited as long as it is two or more.

It is also noted that the configurations of the capacitor elements 20 embedded in the cavity 11X may be all the same, or one or some or all of them may be different.

FIG. 19 is a schematic sectional view of an example of a capacitor element multilayer body for manufacture of the capacitor embedded substrate illustrated in FIG. 18.

As illustrated in FIG. 19, a capacitor element multilayer body 120 including a plurality of capacitor elements 20 integrally stacked via an adhesive layer 110 is disposed in the cavity 11X, and thereby the capacitor embedded substrate 6 illustrated in FIG. 18 can be manufactured.

In the method using the capacitor element multilayer body 120 illustrated in FIG. 19, the core material 11 does not need to be divided, and thereby the capacitor embedded substrate 6 with the entire substrate having high rigidity can be manufactured. Moreover, use of the capacitor element multilayer body 120 can reduce a process of disposing the capacitor elements 20 one by one in the cavity 11X.

According to an exemplary aspect, the capacitor embedded substrate of the present disclosure can be produced by the following method.

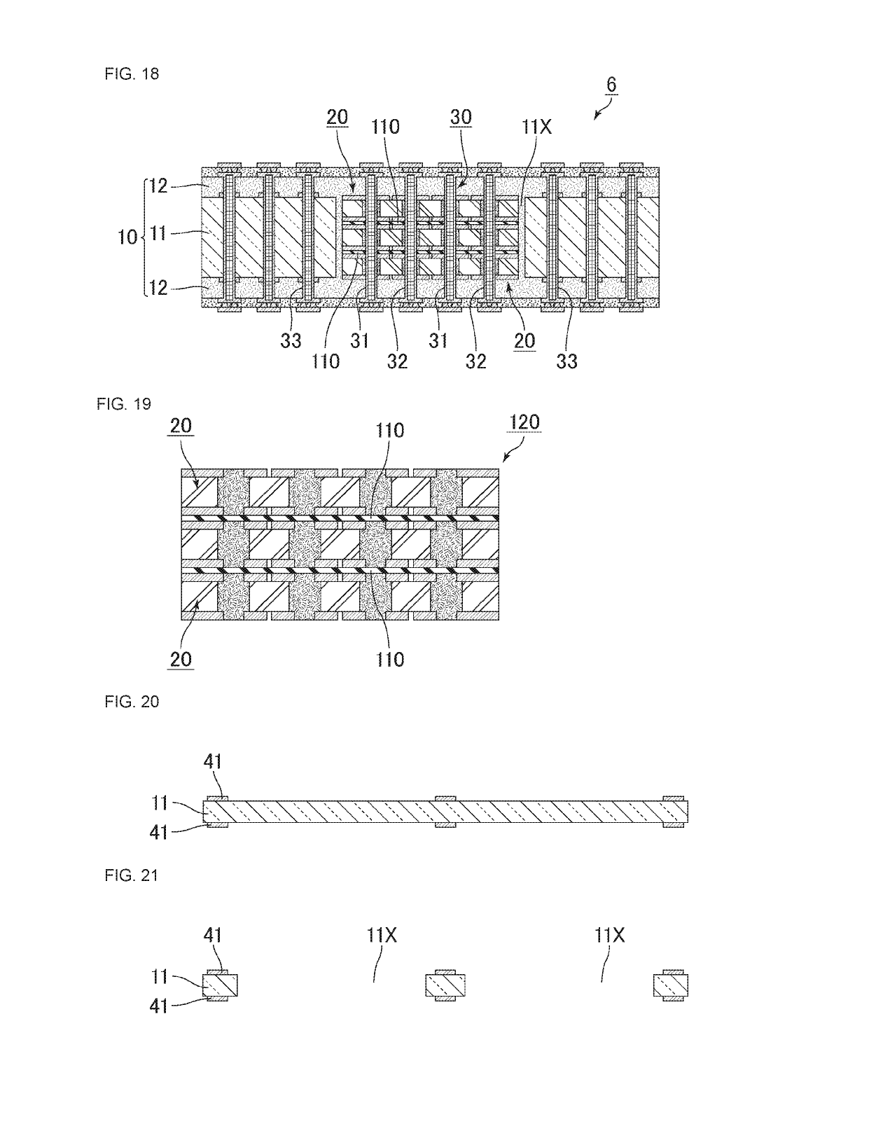

FIG. 20 is a schematic sectional view illustrating an example of a process of forming a first wiring layer on a core material.

In FIG. 20, a first wiring layer 41 is formed in a predetermined region of the core material 11.

For example, a conductor foil, such as a copper foil, attached to both surfaces of the core material 11 is patterned into a predetermined shape, and thereby the first wiring layer 41 can be formed.

FIG. 21 is a schematic sectional view illustrating an example of a process of forming a cavity in a core material.

In FIG. 21, the cavity 11X penetrating the core material 11 at a portion where the first wiring layer 41 is not provided is formed.

FIG. 22 is a schematic sectional view illustrating an example of a process of disposing a capacitor element in a cavity of a core material.

In FIG. 22, the capacitor element 20 is disposed in the cavity 11X of the core material 11 on a support substrate 130.

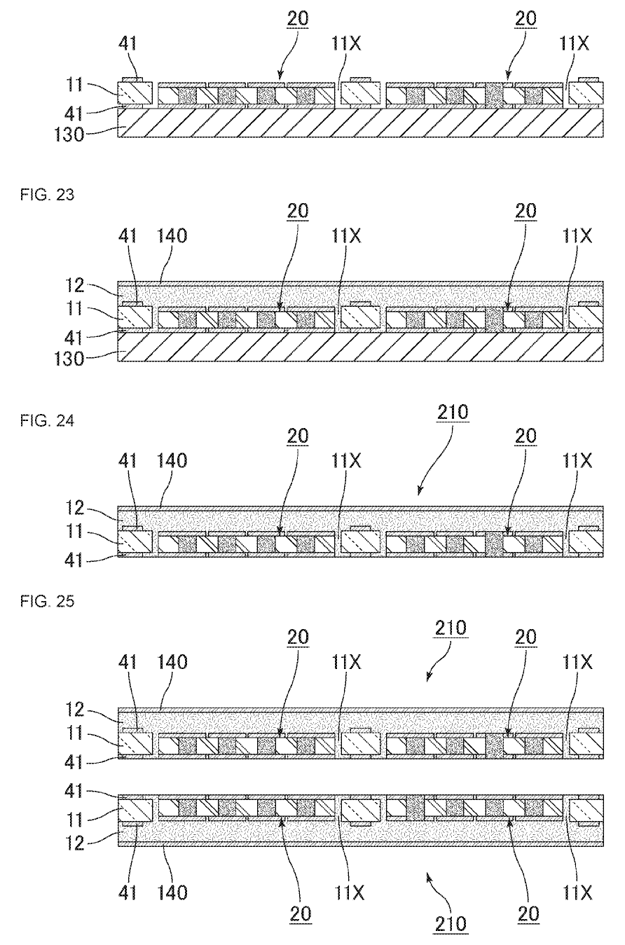

FIG. 23 is a schematic sectional view of an example of a process of performing first resin sealing.

In FIG. 23, resin sealing is performed in such a manner as to cover the core material 11 and the capacitor element 20, and thereby the adhesive layer 12 is formed.

For example, a prepreg is stacked on one main surface of the core material 11 from a side opposite to the support substrate 130, and thereby the adhesive layer 12 can be formed. Thereafter, a conductor foil 140 such as a copper foil is stacked on a surface of the adhesive layer 12.

FIG. 24 is a schematic sectional view illustrating an example of a process of producing a core portion.

In FIG. 24, the support substrate 130 is removed. Accordingly, a core portion 210 is produced.

FIG. 25 is a schematic sectional view illustrating an example of a process of stacking core portions.

For example, when forming the core layer 10 (see FIG. 26) including a plurality of layers of the core material 11, as illustrated in FIG. 25, the core portions 210 are stacked in such a manner that main surfaces on a side without the conductor foil 140 face one another.

On the other hand, when forming the core layer 10 including one layer of the core material 11, a prepreg is stacked on a main surface on a side without the conductor foil 140 to form an adhesive layer, and thereafter, a conductor foil such as a copper foil is stacked.

FIG. 26 is a schematic sectional view illustrating an example of a process of forming a core layer.

In FIG. 26, for example, the core portions 210 are adhered to and integrated with one another via a prepreg, and thereby the core layer 10 is formed.

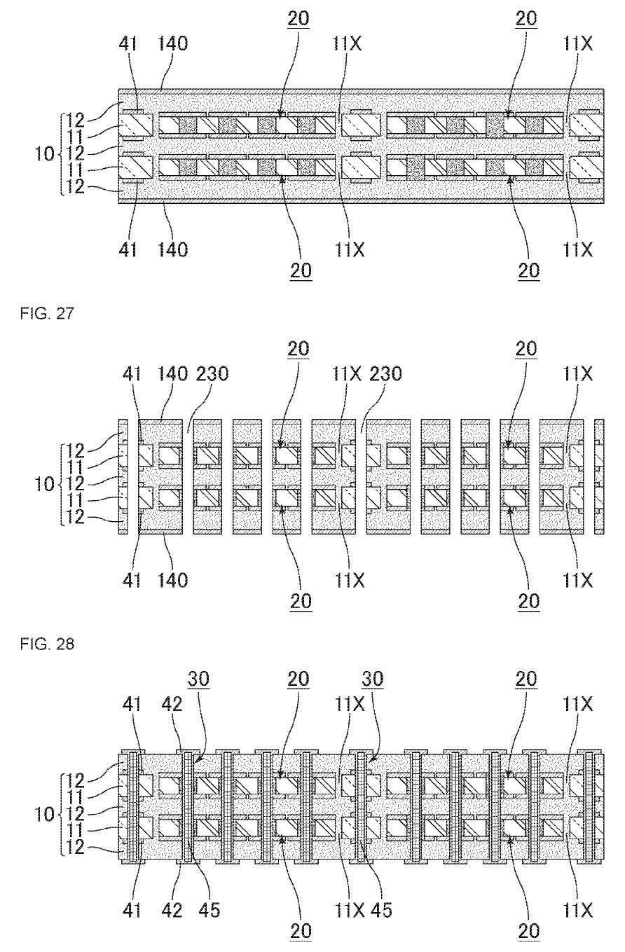

FIG. 27 is a schematic sectional view illustrating an example of a process of forming a through hole penetrating a core layer.

In FIG. 27, a through hole 230 penetrating the core layer 10 is formed.

For example, processing such as drilling is performed to form the through hole 230 penetrating the core material 11 or the capacitor element 20 in the thickness direction. As illustrated in FIG. 27, an insulating material is present between an inner wall surface of the through hole 230 penetrating the capacitor element 20 among the through holes 230 and the capacitor element 20.

FIG. 28 is a schematic sectional view illustrating an example of a process of forming a through conductor.

In FIG. 28, the through conductor 30 is formed on an inner wall surface of the through hole 230.

For example, the inner wall surface of the through hole 230 is metallized with a low-resistance metal, such as copper, gold, or silver, to form the through conductor 30. In forming the through conductor 30, for example, metallization of the inner wall surface of the through hole 230 by electroless copper plating treatment, electrolytic copper plating treatment, or the like facilitates the processing. It is noted that as a method for forming the through conductor 30, other than the method of metallizing the inner wall surface of the through hole 230, a method of filling the through hole 230 with a metal, a composite material of a metal and a resin, or the like may be employed.

As illustrated in FIG. 28, the inside of the through conductor 30 may be filled with a resin material to form the resin filling part 45. Moreover, the conductor foil 140 (see FIG. 27) is patterned into a predetermined shape to form the second wiring layer 42 in an exemplary aspect.

FIG. 29 is a schematic sectional view illustrating an example of a process of performing second resin sealing.

In FIG. 29, resin sealing is performed in such a manner as to cover the core layer 10, and thereby the insulating layer 14 is formed on at least one main surface of the core layer 10.

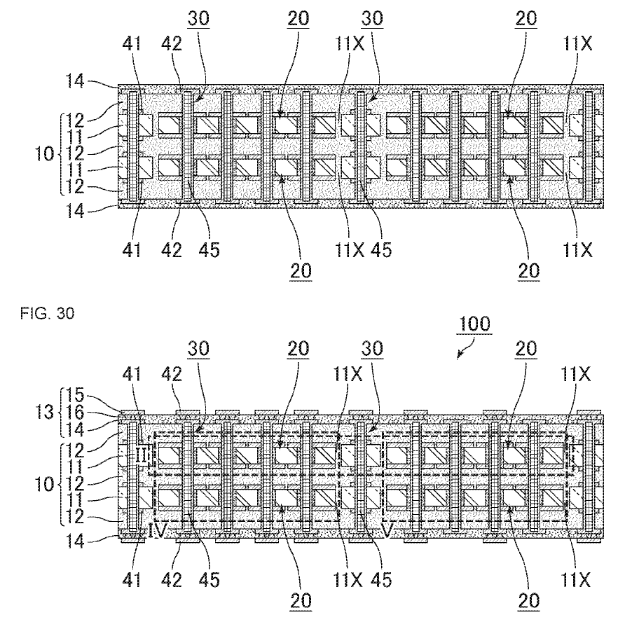

FIG. 30 is a schematic sectional view illustrating an example of a process of forming a via conductor and wiring.

In FIG. 30, the via conductor 16 and the wiring 15 are provided to the insulating layer 14. Accordingly, the redistribution layer 13 is formed.

In the manner described above, a capacitor embedded substrate 100 is produced.

In the capacitor embedded substrate 100 illustrated in FIG. 30, a portion indicated by II corresponds to the capacitor embedded substrate 2, a portion indicated by IV corresponds to the capacitor embedded substrate 4, and a portion indicated by V corresponds to the capacitor embedded substrate 5.

It is noted that the capacitor embedded substrate 1 or 3 can be produced by a method similar to that for the portion indicated by IV as would be appreciated to one skilled in the art. Moreover, the capacitor embedded substrate 6 can be produced by a method similar to that described above by using the capacitor element multilayer body 120 illustrated in FIG. 19.

In general it is noted that the capacitor embedded substrate of the present disclosure is not limited to the above-described embodiments. Various applications and modifications can be made within the scope of the exemplary aspects of the present disclosure regarding the configurations of the capacitor element and the wiring substrate, the manufacturing condition of the capacitor embedded substrate, and the like.

For example, a plurality of capacitor elements may be embedded in a single cavity in a planar direction.

Below, a detailed configuration of the capacitor element 20 will be described.

One capacitor part 70 may be disposed inside the sealing layer 80, or a plurality of capacitor parts 70 may be disposed inside the sealing layer 80. In the case in which a plurality of capacitor parts 70 is disposed inside the sealing layer 80, a through groove penetrating the capacitor part 70 in the thickness direction divides the capacitor part 70 to form capacitor parts 70 adjacent to one another. In this case, the through groove is filled with an insulating material such as the sealing layer 80 in an exemplary aspect.

When the adjacent capacitor parts 70 are divided by the through groove, the adjacent capacitor parts 70 only need to be physically divided by the through groove. Therefore, the adjacent capacitor parts 70 may be electrically divided or may be electrically connected. A width of the through groove, that is, an interval between the adjacent capacitor parts 70, may be constant or may be reduced in the thickness direction.

When a plurality of capacitor parts 70 is disposed inside the sealing layer 80, the plurality of capacitor parts 70 may be disposed in such a manner as to be aligned in a planar direction orthogonal to the thickness direction, may be disposed in such a manner as to be stacked in the thickness direction, or may be disposed by a combination thereof. The plurality of capacitor parts 70 may be disposed regularly or may be disposed irregularly in various exemplary aspects. The capacitor parts 70 may have the same size, shape, and the like, or one or some or all of them may have different sizes, shapes, and the like. In an exemplary aspect, the capacitor parts 70 have the same configuration, but the capacitor part 70 with a different configuration may be included.

Examples of a planar shape of the capacitor part 70 when seen in the thickness direction include polygons, such as a rectangle (square or oblong), a quadrangle other than a rectangle, a triangle, a pentagon, and a hexagon, a circle, an ellipse, and a combination thereof. Moreover, the planar shape of the capacitor part 70 may be an L-shape, a C-shape (backward C-shape), a step shape, or the like.

In an exemplary aspect, the anode plate 71 is made of a valve metal exhibiting a so-called valve action. Examples of the valve metal include simple metals, such as aluminum, tantalum, niobium, titanium, and zirconium, and alloys containing at least one of these metals. Among these, aluminum or an aluminum alloy is preferable.

In an exemplary aspect, a shape of the anode plate 71 is a flat-plate shape, and more preferably, a foil shape. In this way, the term "plate shape" as used herein also includes "foil shape".

The anode plate 71 only should include the porous portion 71B on at least one main surface of the core portion 71A. That is, the anode plate 71 may include the porous portion 71B on only one main surface of the core portion 71A, or may include the porous portion 71B on both main surfaces of the core portion 71A. In an exemplary aspect, the porous portion 71B is a porous layer formed on a surface of the core portion 71A, and more preferably, the porous portion 71B is an etched layer.

In an exemplary aspect, a thickness of the anode plate 71 before etching treatment is 60 μm or more and 200 μm or less. Moreover, a thickness of the core portion 71A unetched after etching treatment can be 15 μm or more and 70 μm or less. A thickness of the porous portion 71B is designed in accordance with a required withstand voltage and electrostatic capacity, and preferably, the total of the porous portion 71B on both sides of the core portion 71A is 10 μm or more and 180 μm or less.

In an exemplary aspect, a pore diameter of the porous portion 71B is 10 nm or more and 600 nm or less. Note that the pore diameter of the porous portion 71B refers to a median diameter D50 measured by a mercury porosimeter. For example, various conditions in etching can be adjusted to control the pore diameter of the porous portion 71B.

The dielectric layer 73 provided on a surface of the porous portion 71B is porous reflecting the surface condition of the porous portion 71B, and has a fine uneven surface shape. In an exemplary aspect, the dielectric layer 73 comprises an oxide film made of the valve metal described above. For example, when an aluminum foil is used as the anode plate 71, an anodizing treatment (also referred to as a chemical conversion treatment) is performed on a surface of the aluminum foil in an aqueous solution including ammonium adipate or the like, and thereby the dielectric layer 73 made of an oxide film can be formed.

A thickness of the dielectric layer 73 is designed in accordance with a required withstand voltage and electrostatic capacity, and is preferably, 10 nm or more and 100 nm or less in an exemplary aspect.

When the cathode layer 72 includes a solid electrolyte layer in an exemplary aspect, examples of a material included in the solid electrolyte layer include conductive polymers, such as polypyrroles, polythiophenes, and polyanilines. Among these, polythiophenes are preferable, and Poly(3,4-ethylenedioxythiophene) called PEDOT is particularly preferable. Moreover, the conductive polymer may include a dopant such as polystyrene sulfonic acid (PSS). Note that, preferably, the solid electrolyte layer includes an inner layer filling a pore (recess) of the dielectric layer 73 and an outer layer covering the dielectric layer 73.

In an exemplary aspect, a thickness of the solid electrolyte layer from the surface of the porous portion 71B is 2 μm or more and 20 μm or less.

The solid electrolyte layer is formed by, for example, a method of forming a polymerized film of Poly(3,4-ethylenedioxythiophene) or the like on a surface of the dielectric layer 73 by using a treatment liquid containing a monomer such as 3,4-ethylenedioxythiophene, a method of applying a dispersion liquid of a polymer, such as Poly(3,4-ethylenedioxythiophene), to the surface of the dielectric layer 73 and drying it, or the like.

The solid electrolyte layer can be formed in a predetermined region by applying the treatment liquid or dispersion liquid described above to the surface of the dielectric layer 73 by a method, such as sponge transfer, screen printing, dispenser application, or inkjet printing.

When the cathode layer 72 includes a conductor layer in an exemplary aspect, the conductor layer includes at least one of a conductive resin layer or a metal layer. The conductor layer may include only a conductive resin layer or include only a metal layer. Preferably, the conductor layer covers the entire surface of the solid electrolyte layer.

Examples of the conductive resin layer include a conductive adhesive layer including at least one kind of conductive filler selected from the group consisting of a silver filler, a copper filler, a nickel filler, and a carbon filler.

Examples of the metal layer include a metal plating film and a metal foil. Preferably, the metal layer is made of at least one kind of metal selected from the group consisting of nickel, copper, silver, and alloys containing these metals as main components. Note that "main component" refers to an elemental component having the largest weight ratio.

The conductor layer includes, for example, a carbon layer provided on a surface of the solid electrolyte layer, and a copper layer provided on a surface of the carbon layer.

The carbon layer is provided to electrically and mechanically connect the solid electrolyte layer and the copper layer to one another. The carbon layer can be formed in a predetermined region by applying a carbon paste on the surface of the solid electrolyte layer by a method, such as sponge transfer, screen printing, dispenser application, or inkjet printing. Preferably, a thickness of the carbon layer is 2 μm or more and 20 μm or less.

The copper layer can be formed in a predetermined region by applying a copper paste on the surface of the carbon layer by a method, such as sponge transfer, screen printing, spray application, dispenser application, or inkjet printing. Preferably, a thickness of the copper layer is 2 μm or more and 20 μm or less.

The insulating mask layers 74 and 75 include an insulating material. In this case, preferably, the insulating mask layers 74 and 75 contain an insulating resin.

Examples of the insulating resin contained in the insulating mask layers 74 and 75 include a polyphenylsulfone resin, a polyethersulfone resin, a cyanate ester resin, a fluororesin (tetrafluoroethylene, tetrafluoroethylene-perfluoroalkyl vinyl ether copolymer, and the like), a polyimide resin, a polyamide-imide resin, an epoxy resin, and a derivative or a precursor thereof.

The insulating mask layers 74 and 75 may include the same resin as the sealing layer 80. Unlike the sealing layer 80, when the insulating mask layers 74 and 75 contain an inorganic filler, a capacitance effective portion of the capacitor part 70 may be adversely affected. Therefore, the insulating mask layers 74 and 75 are preferably made of a resin-alone system.

The insulating mask layers 74 and 75 can be formed in a predetermined region by, for example, applying a mask material, such as a composition including an insulating resin, to a surface of the porous portion 71B by a method, such as sponge transfer, screen printing, dispenser application, or inkjet printing.

The insulating mask layers 74 and 75 may be formed with respect to the porous portion 71B before or after formation of the dielectric layer 73.

The sealing layer 80 includes an insulating material. In this case, preferably, the sealing layer 80 contains an insulating resin.

Examples of the insulating resin contained in the sealing layer 80 include an epoxy resin, a phenol resin, and the like.

In an exemplary aspect, the sealing layer 80 further contains a filler such as an inorganic filler.

Examples of the inorganic filler contained in the sealing layer 80 include silica particles, alumina particles, and the like.

Between the capacitor part 70 and the sealing layer 80, for example, a layer such as a stress relief layer or a moisture-proof film may be provided.

In an exemplary aspect, the anode through conductor 81 is electrically connected to a wall surface of the anode plate 71 exposed to a through hole provided with the anode through conductor 81. In other words, the anode through conductor 81 may be electrically connected to the anode plate 71 at an inner wall surface of the through hole provided with the anode through conductor 81.

The anode through conductor 81 may be electrically connected to the wall surface of the anode plate 71 via an anode connection layer. In this case, the anode connection layer functions as a barrier layer for the anode plate 71, more specifically, a barrier layer for the core portion 71A and the porous portion 71B. When the anode connection layer functions as a barrier layer for the anode plate 71, dissolution of the anode plate 71 caused during chemical liquid treatment for forming the wiring layer is suppressed, and eventually, entering of a chemical liquid into the capacitor part 70 is suppressed, which easily improves reliability.

In an exemplary aspect, the anode connection layer includes a metal layer including nickel as a main component. In this case, damage to metal (for example, aluminum) included in the anode plate 71 is reduced, and thereby a barrier property of the anode connection layer with respect to the anode plate 71 easily improves.

For example, after a zincate treatment is performed on the wall surface of the anode plate 71 made of aluminum or an aluminum alloy, an electroless nickel plating treatment is performed, and thereby the anode connection layer including a metal layer including nickel as a main component can be formed. Note that the anode connection layer may include, in order from the anode plate 71, a metal layer including zinc as a main component and a metal layer including nickel as a main component.

It is also noted that the anode through conductor 81 may be directly connected to the wall surface of the anode plate 71 without the intervention of the anode connection layer.

Examples of a component material included in the cathode via conductor 82 include a metal material containing a low-resistance metal, such as silver, gold, or copper.

The cathode via conductor 82 is formed by, for example, performing a plating treatment on an inner wall surface of a through hole penetrating the sealing layer 80 in the thickness direction with the above-mentioned metal material, or filling a conductive paste into the through hole and then performing a heat treatment.

### REFERENCE SIGNS LIST

1, 1A, 2, 3, 4, 5, 6 capacitor embedded substrate

10 core layer

10a first main surface

10b second main surface

10c glass cloth

11 core material

11X cavity

12 adhesive layer

13 redistribution layer

14 insulating layer

15 wiring

16 via conductor

20 capacitor element

20A first capacitor element

20B second capacitor element

21 first electrode

22 second electrode

30, 30PD, 30S through conductor

31 first through conductor

32 second through conductor

33 third through conductor

34 fourth through conductor

41 first wiring layer

42 second wiring layer

45 resin filling part

50 load

55 power supply

60 interface

70 capacitor part

71 anode plate

71A core portion

71B porous portion

72 cathode layer

73 dielectric layer

74, 75 insulating mask layer

80 sealing layer

81 anode through conductor

82 cathode via conductor

100 capacitor embedded substrate

110 adhesive layer

120 capacitor element multilayer body

130 support substrate

140 conductor foil

210 core portion

230 through hole

1. A capacitor embedded substrate comprising:
a core layer including at least one layer of a core material that includes a cavity;
a capacitor element embedded in the cavity of the core material; and
at least one through conductor that penetrates the core layer in a thickness direction of the core layer, the at least one through conductor including:
a first through conductor that penetrates the capacitor element in the core layer to be electrically connected to a load and a power supply; and
a second through conductor that penetrates the capacitor element in the core layer at a position apart from the first through conductor to be electrically connected to the load and the power supply,
wherein the first through conductor is electrically connected to a first electrode of the capacitor element, and
wherein the second through conductor is electrically connected to a second electrode of the capacitor element, the second electrode having a polarity different from a polarity of the first electrode.

2. The capacitor embedded substrate according to claim 1, wherein the at least one through conductor further includes a third through conductor that penetrates the core material without penetrating the capacitor element in the core layer to be electrically connected to an interface and the load.

3. The capacitor embedded substrate according to claim 2, wherein:
the core layer includes a first main surface and a second main surface that faces the first main surface in the thickness direction, and
the first through conductor and the second through conductor are electrically connected to the load at an end portion closer to the first main surface and electrically connected to the power supply at an end portion closer to the second main surface.

4. The capacitor embedded substrate according to claim 3, wherein the third through conductor is electrically connected to the load at an end portion closer to the first main surface and electrically connected to the interface at an end portion closer to the second main surface.

5. The capacitor embedded substrate according to claim 3, wherein, in a plan view of the core material, the third through conductor is disposed on an outer peripheral side of the first through conductor and the second through conductor.

6. The capacitor embedded substrate according to claim 1, wherein:
the core layer includes a first main surface and a second main surface that faces the first main surface in the thickness direction, and
the first through conductor and the second through conductor are electrically connected to the load at an end portion closer to the first main surface and electrically connected to the power supply at an end portion closer to the second main surface.

7. The capacitor embedded substrate according to claim 4, wherein the first through conductor and the second through conductor are electrically connected to the load directly below the load in a plan view of the core material.

8. The capacitor embedded substrate according to claim 1, wherein:
the at least one layer of the core material includes a layer comprising a plurality of cavities, and
the capacitor element comprises a plurality of capacitor elements embedded in each of the plurality of cavities, respectively.

9. The capacitor embedded substrate according to claim 1, wherein
the core layer includes a plurality of layers of the core material, and
at least one layer of the core material includes the cavity.

10. The capacitor embedded substrate according to claim 9, wherein:
two or more layers of the plurality of layers of the core material include respective cavities, and
the capacitor element comprises a plurality of capacitor elements embedded in each of the cavities, respectively.

11. The capacitor embedded substrate according to claim 10, wherein the plurality of capacitor elements includes a first capacitor element and a second capacitor element embedded in the respective cavities of the core material of different layers of the two or more layers.

12. The capacitor embedded substrate according to claim 11, wherein the first through conductor penetrates the first capacitor element and is electrically connected to a first electrode of the first capacitor element, and also penetrates the second capacitor element and is electrically connected to a first electrode of the second capacitor element, which has a same polarity as a polarity of the first electrode of the first capacitor element.

13. The capacitor embedded substrate according to claim 12, wherein the second through conductor penetrates the first capacitor element and is electrically connected to a second electrode of the first capacitor element, and also penetrates the second capacitor element and is electrically connected to a second electrode of the second capacitor element, which has a same polarity as a polarity of the second electrode of the first capacitor element.

14. The capacitor embedded substrate according to claim 10, wherein:
the capacitor element includes a first capacitor element and a second capacitor element embedded in the respective cavities of the core material of different layers, and
the at least one through conductor further includes a fourth through conductor that penetrates the capacitor element in the core layer at a position apart from the first through conductor and the second through conductor.

15. The capacitor embedded substrate according to claim 14, wherein:
the first through conductor penetrates the first capacitor element and is electrically connected to a first electrode of the first capacitor element, and also penetrates the second capacitor element and is not electrically connected to either a first electrode of the second capacitor element or a second electrode of the second capacitor element, and
the first electrode of the second capacitor element has a same polarity as a polarity of the first electrode of the first capacitor element, and the second electrode of the second capacitor element has a same polarity as a polarity of the second electrode of the first capacitor element.

16. The capacitor embedded substrate according to claim 15, wherein the second through conductor penetrates the first capacitor element and is electrically connected to the second electrode of the first capacitor element, and also penetrates the second capacitor element and is electrically connected to the first electrode of the second capacitor element.

17. The capacitor embedded substrate according to claim 16, wherein the fourth through conductor penetrates the first capacitor element and is not electrically connected to either the first electrode of the first capacitor element or the second electrode of the first capacitor element, and wherein the fourth through conductor also penetrates the second capacitor element and is electrically connected to the second electrode of the second capacitor element.

18. The capacitor embedded substrate according to claim 1, wherein a plurality of capacitor elements is embedded in the cavity of the core material of a same layer of the at least one layer of the core material.

19. The capacitor embedded substrate according to claim 1, wherein:
the capacitor element includes a capacitor part and a sealing layer that covers at least one main surface of the capacitor part, and
the capacitor part includes an anode plate including a porous portion on at least one main surface of a core portion, a dielectric layer on a surface of the porous portion, and a cathode layer on a surface of the dielectric layer.

20. A capacitor embedded substrate comprising:
a core layer including at least one layer of a core material that includes a cavity;
a capacitor element embedded in the cavity of the core material; and
at least one through conductor that penetrates the core layer in a thickness direction of the core layer, the at least one through conductor including:
a first through conductor that penetrates the capacitor element in the core layer; and
a second through conductor that penetrates the capacitor element in the core layer at a position apart from the first through conductor,
wherein the first through conductor is electrically connected to a first electrode of the capacitor element, and
wherein the second through conductor is electrically connected to a second electrode of the capacitor element, the second electrode having a polarity different from a polarity of the first electrode.
